(19) United States
(12) Patent Application Publication
(10) Pub. No.: US 2025/0293643 A1
(43) Pub. Date: Sep. 18, 2025

(54) SENSING TRANS-IMPEDANCE AMPLIFIER (TIA) OUTPUT IN LINEAR PLUGGABLE OPTICS

(71) Applicant: MaxLinear, Inc., Carlsbad, CA (US)

(72) Inventor: Mario Milicevic, Irvine, CA (US)

(73) Assignee: MaxLinear, Inc., Carlsbad, CA (US)

(21) Appl. No.: 19/080,735

(22) Filed: Mar. 14, 2025

Related U.S. Application Data
(60) Provisional application No. 63/565,492, filed on Mar. 14, 2024.

(51) Int. Cl. H03F 3/08; H04B 10/69

(52) U.S. Cl. CPC H03F 3/08; H04B 10/6971

(57) ABSTRACT

A device may include one or more of a transmit path, a receive path, or an optical interface receiver. The transmit path may include an electrical-optical interface that may receive an electrical signal and send an optical signal. The receive path may include a trans-impedance amplifier (TIA) that may send a bypass signal. The optical interface receiver may be coupled to the receive path. The optical interface receiver may sense the bypass signal.

### RELATED APPLICATION

This application claims the benefit of U.S. Provisional Application No. 63/565,492, filed Mar. 14, 2024, the disclosure of which is incorporated herein by reference in its entirety for all purposes.

The examples discussed in the present disclosure are related to linear pluggable optics and associated methods for sensing trans-impedance amplifier output.

### BACKGROUND

Unless otherwise indicated herein, the materials described herein are not prior art to the claims in the present application and are not admitted to be prior art by inclusion in this section.

A device may have an electrical interface coupled to an optical interface via a digital signal processor. Using a digital signal processor may add to the power usage of the device. Therefore, methods of reducing power in the device while maintaining performance of the device may be useful.

The subject matter claimed in the present disclosure is not limited to examples that solve any disadvantages or that operate only in environments such as those described above. Rather, this background is only provided to illustrate one example technology area where some examples described in the present disclosure may be practiced.

### SUMMARY

A device may include one or more of a transmit path, a receive path, or an optical interface receiver. The transmit path may include an electrical-optical interface that may receive an electrical signal and send an optical signal. The receive path may include a trans-impedance amplifier (TIA) that may send a bypass signal. The optical interface receiver may be coupled to the receive path. The optical interface receiver may sense the bypass signal.

A method may include one or more of: receiving, on a receive path, a bypass signal from a trans-impedance amplifier (TIA); or sensing, on the receive path, the bypass signal using an optical interface receiver coupled to the receive path.

A device may include a transmit path and/or a receive path. The transmit path may include one or more of: an electrical interface receiver; one or more of a retimer or a gearbox; or an optical interface transmitter. The electrical interface receiver may receive an electrical signal. The one or more of the re-timer or the gearbox may receive the electrical signal from the electrical interface receiver. The optical interface transmitter may receive the electrical signal from one or more of the re-timer or the gearbox and transmit an optical signal. The receive path may include one or more of a TIA, a bypass path, or an optical interface receiver. The TIA may receive a signal and generate a bypass signal. The bypass path may send the bypass signal from the TIA. The optical interface receiver may sense the bypass signal.

The objects and advantages of the examples will be realized and achieved at least by the elements, features, and combinations particularly pointed out in the claims.

Both the foregoing general description and the following detailed description are given as examples and are explanatory and are not restrictive of the invention, as claimed.

### BRIEF DESCRIPTION OF THE DRAWINGS

Examples will be described and explained with additional specificity and detail through the use of the accompanying drawings in which:

FIG. 1 illustrates an example of an electrical interface coupled to an optical/fiber interface via a digital signal processor (DSP).

FIG. 2 illustrates example retiming application.

FIG. 3 illustrates an example of a device that may sense trans-impedance amplifier (TIA) output in linear pluggable optics.

FIG. 4 illustrates an example process flow for sensing TIA output in linear pluggable optics.

FIG. 5 illustrates an example process flow for sensing TIA output in linear pluggable optics.

FIG. 6 illustrates an example process flow for sensing TIA output in linear pluggable optics.

FIG. 7 illustrates a block diagram of an example system operable to sense TIA output in linear pluggable optics.

FIG. 8 illustrates a diagrammatic representation of a machine in the example form of a computing device within which a set of instructions, for causing the machine to perform any one or more of the methods discussed herein, may be executed.

### DESCRIPTION

A device may have an electrical interface coupled to an optical interface via a digital signal processor. Because of the coupling between the electrical interface to the DSP and the coupling between the optical interface to the DSP, the device may use an excessive amount of power and/or include components that do not enhance the performance of the device. In some cases, the device may have a receive path and a transmit path in which each path may be coupled to a digital signal processor (DSP). For purposes of this disclosure, “coupled” may refer to components that may be directly coupled or indirectly coupled (e.g., electrical, optical, mechanical, or the like).

The device may be reduced in cost and power by eliminating the DSP. However, for applications that use a retiming application on a transmit path, eliminating the DSP may lead to a reduction in functionality. For example, some DSP functionalities such as pre-digital distortion may be used by a retiming application on a transmit path. Alternatively or in addition, for short links, a DSP may not be used. In some other examples, a DSP may be used for the transmit path but not for a receive path.

A device for sensing TIA output in linear pluggable optics may be used to reduce the amount of power usage compared to a baseline amount of power usage and/or enhance the performance of the device compared to a baseline amount of performance. The device may include one or more of a transmit path, a receive path, or an optical interface receiver. The transmit path may include an electrical-optical interface that may receive an electrical signal and send an optical signal. The receive path may include a trans-impedance amplifier (TIA) that may send a bypass signal. The optical interface receiver may be coupled to the receive path. The optical interface receiver may sense the bypass signal.

A method for sensing TIA output in linear pluggable optics may be used. In one example, a method may include receiving, on a receive path, a bypass signal from a trans-impedance amplifier (TIA); and sensing, on the receive path, the bypass signal using an optical interface receiver coupled to the receive path.

A device for sensing TIA output in linear pluggable optics may include a transmit path and/or a receive path. The transmit path may include one or more of: an electrical interface receiver; one or more of a retimer or a gearbox; or an optical interface transmitter. The electrical interface receiver may receive an electrical signal. The one or more of the re-timer or the gearbox may receive the electrical signal from the electrical interface receiver. The optical interface transmitter may receive the electrical signal from one or more of the re-timer or the gearbox and transmit an optical signal. The receive path may include one or more of a TIA, a bypass path, or an optical interface receiver. The TIA may receive a signal and generate a bypass signal. The bypass path may send the bypass signal from the TIA. The optical interface receiver may sense the bypass signal.

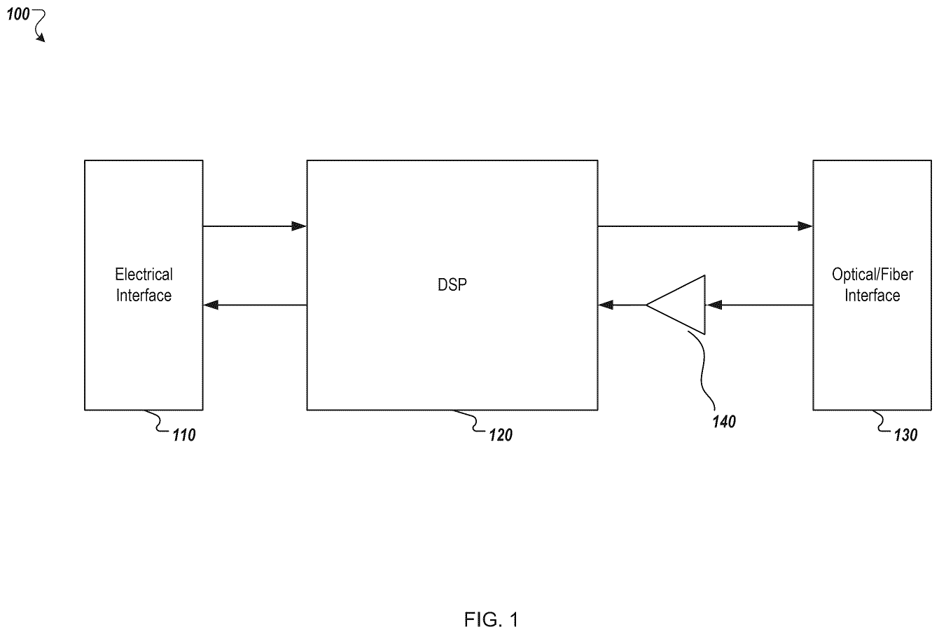

FIG. 1 illustrates an application of digital signal processing within a fiber optic module 100. For example, pluggable modules for data centers may be implemented as shown. An electrical interface 110 may be coupled to a DSP 120. The DSP may be coupled to the optical/fiber interface 130. The electrical interface may be coupled to a switch (not shown) via an electrical connection (e.g., an electrical wire such as a copper wire). The optical/fiber interface may be coupled to a switch (not shown) via an optical connection (e.g., a fiber optic connection).

On the transmit path, the electrical interface 110 may receive a signal from an electrical connection and direct a digital signal to the DSP 120. The DSP 120 may process the signal and direct the processed signal to the optical/fiber interface 130 for transmission via an optical connection.

On the receive path, an optical connection may direct a signal to the optical/fiber interface 130. The optical/fiber interface may direct a current to the TIA 140. The TIA 140 may amplify the current and convert the amplified current to a voltage to be directed to the DSP 120. The DSP 120 may receive the voltage via a receive input which may re-time the voltage and send the retimed voltage to the electrical interface 110 for transmission to a switch via an electrical connection.

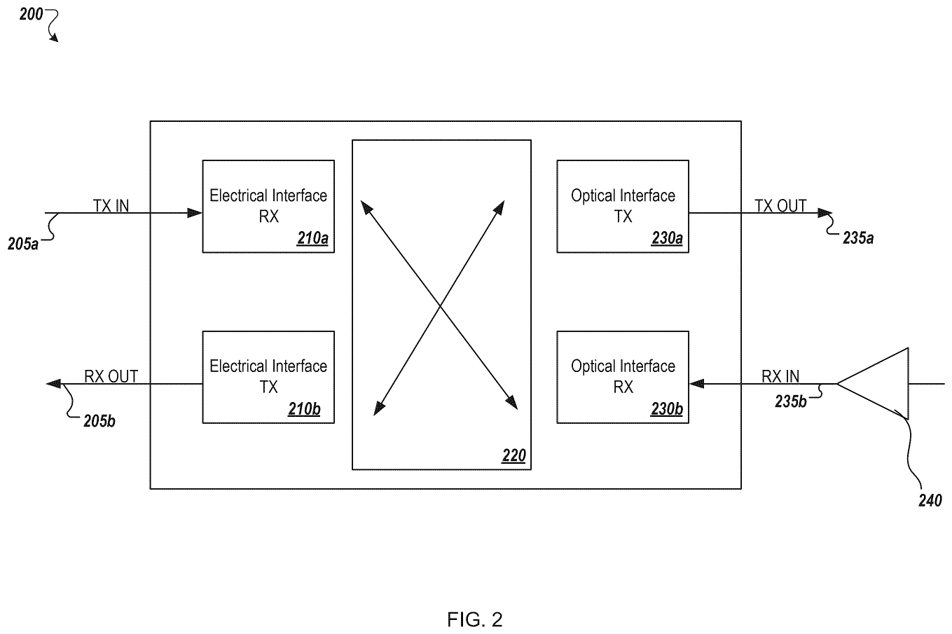

As illustrated in FIG. 2, a fiber optic module 200 may include an electrical interface receiver 210a, a DSP 220, an optical interface transmitter 230a, a trans-impedance amplifier 240, an optical interface receiver 230b, and an electrical interface transmitter 210b.

On the transmit path, a signal may be directed from a transmit (TX) IN 205a to an electrical interface receiver 210a. The electrical interface receiver 210a may direct a signal to the DSP 220. The DSP 220 may direct a signal to the optical interface transmitter 230a. The optical interface transmitter 230a may direct a signal to a TX OUT 235a.

On the receive path, a current may be received at the TIA 240, amplified, and converted to a voltage which may be directed via receive (RX) IN 235b to an optical interface receiver 230b. The optical interface receiver 230b may direct the signal to the DSP 220. The DSP 220 may direct the signal to an electrical interface transmitter 210b. The electrical interface transmitter 210b may direct the signal to an RX OUT 205b.

The DSP 220 may be used for retiming applications. The electrical and optical sides may have paths to receive a signal, retime the signal, and output the signal at a different rate. That is, the electrical and optical sides may have a path that allows for retiming for a selected output rate, which may be output at a different rate.

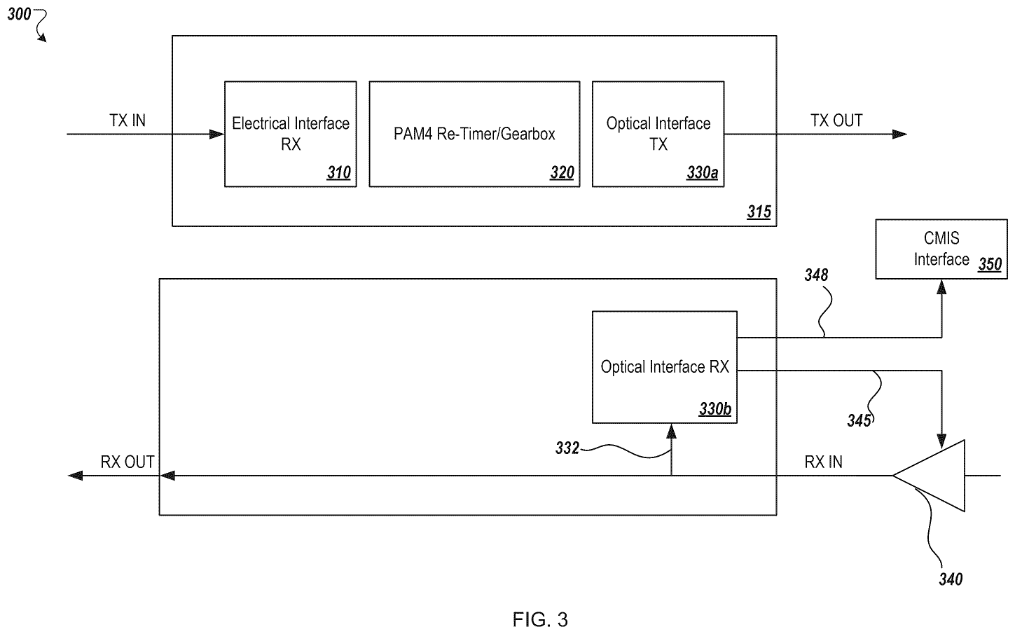

As illustrated in FIG. 3, a device 300 (e.g., a fiber optic module) may be implemented for linear pluggable optics. The device 300 may include a transmit path including an electrical-optical interface 315 that may receive an electrical signal and send an optical signal. The device 300 may include a receive path including a trans-impedance amplifier (TIA) 340 that may send a bypass signal. The device 300 may include an optical interface receiver 330b that may be coupled to the receive path. The optical interface receiver 330b may sense the bypass signal.

A subset of linear pluggable optics is analog receive optics. The transmit path may include a retiming interface on the transmit path from the electrical interface receiver 310 to the optical interface transmitter 330a. The retiming interface may be a pulse amplitude modulation (PAM) 4 re-timer/gearbox 320. The pulse amplitude modulation 4 (PAM4) re-timer/gearbox 320 may retime the electrical signal received from the electrical interface receiver 310 and perform signal processing such as digital pre-distortion. On the receive path, the signal may be received from the TIA 340 and may be directed to RX OUT without any signal processing. That is, the signal may be received from the TIA 340 and sent directly to RX OUT without any equalization. The optical interface receiver 330b may sense, via connection 332, the signal received from TIA 340. The optical interface receiver 330b may send a sensed bypass signal (e.g., a feedback signal) to TIA 340 using connection 345. Alternatively or in addition, the optical interface receiver 330b may send a sensed bypass signal to a module interface (e.g., a common management interface specification (CMIS) interface 350) using connection 348. The output from the optical interface receiver may be processed without using a digital signal processor.

The module interface may include a master controller unit (MCU) which may control the module interface and control communication between the module interface and a switch.

The optical interface receiver 330b may send feedback to the TIA 340 using the sensed bypass signal. The optical interface receiver 330b may send feedback to the TIA 340 using one or more signal conditions of the sensed bypass signal. For example, the feedback may inform the TIA 340 of output signal conditions in order to generate an enhanced link. The feedback may be used to bias the TIA 340 in some settings or inform the TIA 340 of the kind of signal conditions such as voltage swing or channel roll-off. Alternatively or in addition, the feedback may be used to adjust an internal gain of the TIA 340. Alternatively or in addition, the feedback may be used to adjust an equalization of the TIA 340.

Alternatively or in addition, the signal from the optical interface receiver 330b may provide the transmit statistics/characteristics of the receive path to the module interface (e.g., CMIS interface 350). Alternatively or in addition, the signal from the optical interface receiver may be used to monitor the forward error correction (FEC) statistics (e.g., KP4 FEC) in the receive path, and/or collect the FEC statistics in the receive path, and/or report the FEC statistics to a module interface (e.g., CMIS interface 350).

The power for the receive path may be reduced which may reduce the power for the device 300. For example, the receive path may use a duty cycle to reduce power consumption. That is, the receive portion of the device 300 may be powered down so that it may be operational once in a selected time period (e.g., a second, a minute, an additional threshold, or the like).

Alternatively or in addition, the device 300 may include a transmit path. The transmit path may include an electrical interface receiver 310 that may receive an electrical signal. The transmit path may include a re-timer and/or gearbox (e.g., PAM 4 re-timer gearbox 320) that may receive the electrical signal from the electrical interface receiver 310. The transmit path may include an optical interface transmitter 330a that may receive the electrical signal from the re-timer and/or gearbox and transmit an optical signal.

The device 300 may include a receive path. The receive path may include a TIA 340 that may receive a signal. The receive path may include a bypass path that may send a bypass signal from the TIA 340. The receive path may include an optical interface receiver 330b that may sense the bypass signal.

The optical interface receiver 330b may send a sensed bypass signal to a module interface (e.g., CMIS interface 350). The optical interface receiver 330b may send feedback to the TIA 340 using the sensed bypass signal. The optical interface receiver 330b may send feedback to the TIA 340 using one or more signal conditions of the sensed bypass signal. The feedback may be used to adjust an internal gain of the TIA 340. The feedback may be used to adjust an equalization of the TIA 340.

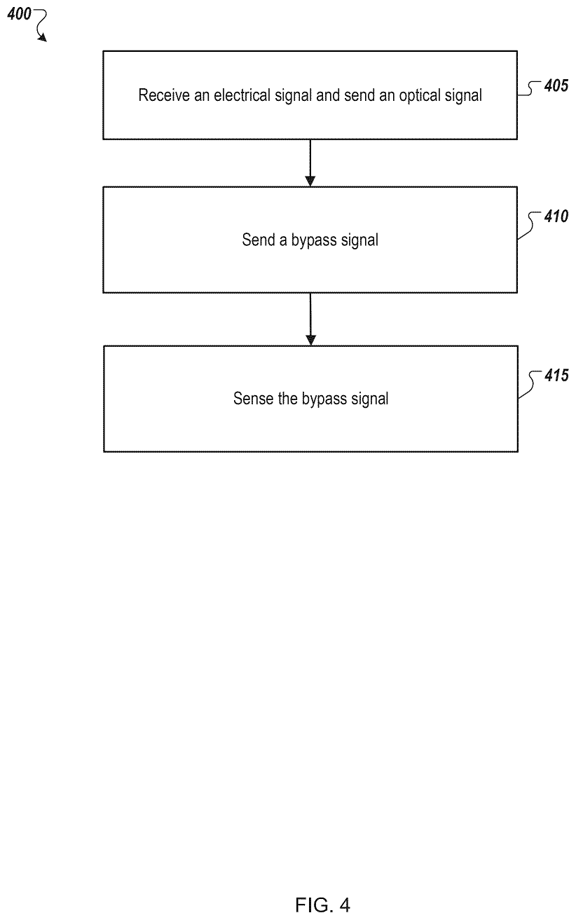

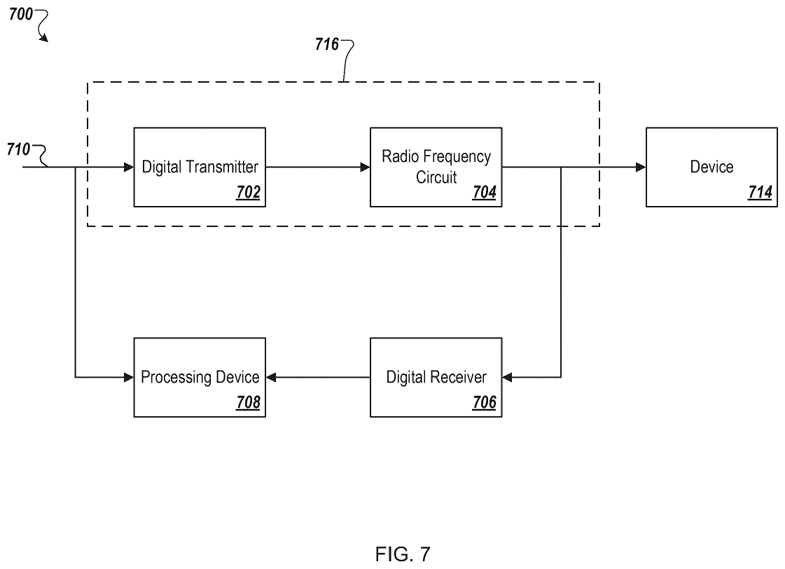

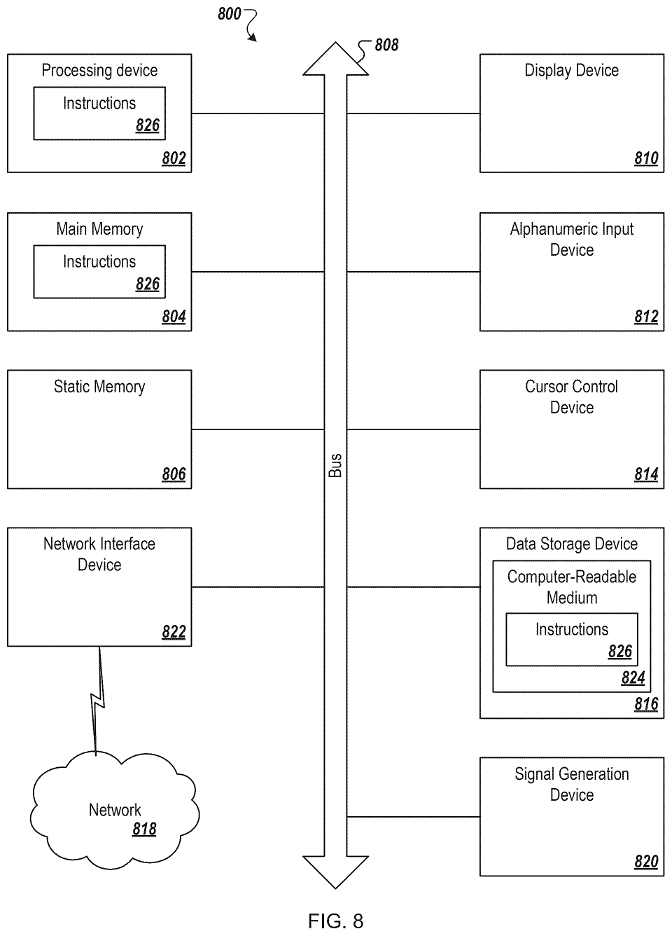

FIG. 4 illustrates a process flow of an example method 400 of sensing trans-impedance amplifier (TIA) output in linear pluggable optics, in accordance with at least one example described in the present disclosure. The method 400 may be arranged in accordance with at least one example described in the present disclosure. The method 400 may be performed by processing logic that may include hardware (circuitry, dedicated logic, etc.), software (such as is run on a computer system or a dedicated machine), or a combination of both, which processing logic may be included in the processor (e.g., the processing device 802 of FIG. 8), the communication system 700 of FIG. 7, or another device, combination of devices, or systems.

The method 400 may begin at block 405 where the processing logic may receive an electrical signal and send an optical signal. At block 410, the processing logic may send a bypass signal. At block 415, the processing logic may sense the bypass signal.

Modifications, additions, or omissions may be made to the method 400 without departing from the scope of the present disclosure. For example, in some examples, the method 400 may include any number of other components that may not be explicitly illustrated or described.

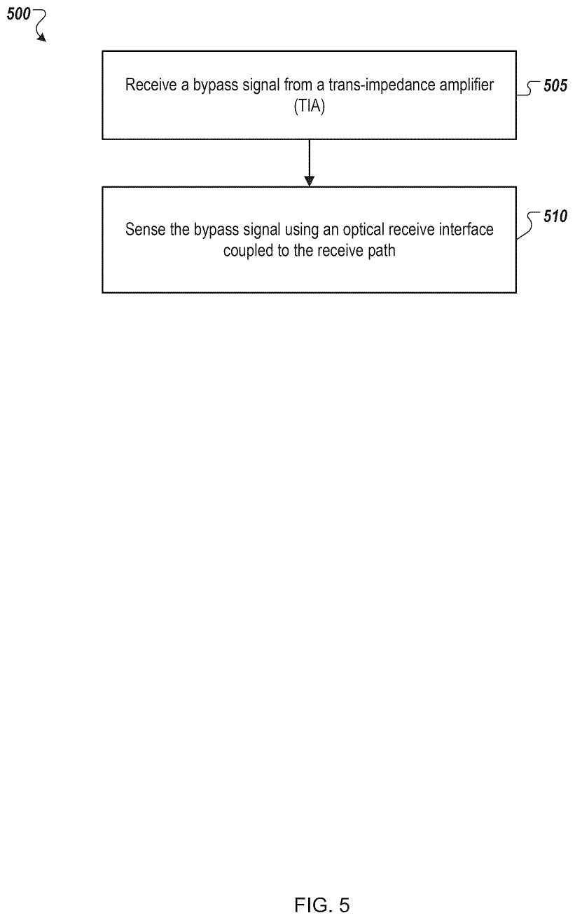

FIG. 5 illustrates a process flow of an example method 500 of sensing TIA output in linear pluggable optics, in accordance with at least one example described in the present disclosure. The method 500 may be arranged in accordance with at least one example described in the present disclosure. The method 500 may be performed by processing logic that may include hardware (circuitry, dedicated logic, etc.), software (such as is run on a computer system or a dedicated machine), or a combination of both, which processing logic may be included in the processor (e.g., the processing device 802 of FIG. 8), the communication system 700 of FIG. 7, or another device, combination of devices, or systems.

The method 500 may begin at block 505 where the processing logic may receive, on a receive path, a bypass signal from a trans-impedance amplifier (TIA). At block 510, the processing logic may sense, on the receive path, the bypass signal using an optical interface receiver coupled to the receive path.

The processing logic may send, using the optical receive interface, a sensed bypass signal to a module interface. The processing logic may send, using the optical receive interface, feedback to the TIA from a sensed bypass signal. The processing logic may send, using the optical receive interface, the feedback to the TIA using one or more signal conditions of the sensed bypass signal. The processing logic may adjust an internal gain of the TIA using the feedback. The processing logic may monitor forward error-correction (FEC) statistics of the receive path, collect FEC statistics of the receive path, and/or send FEC statistics of the receive path to the module interface (e.g., KP4 FEC statistics via CMIS interface).

Modifications, additions, or omissions may be made to the method 500 without departing from the scope of the present disclosure. For example, in some examples, the method 500 may include any number of other components that may not be explicitly illustrated or described.

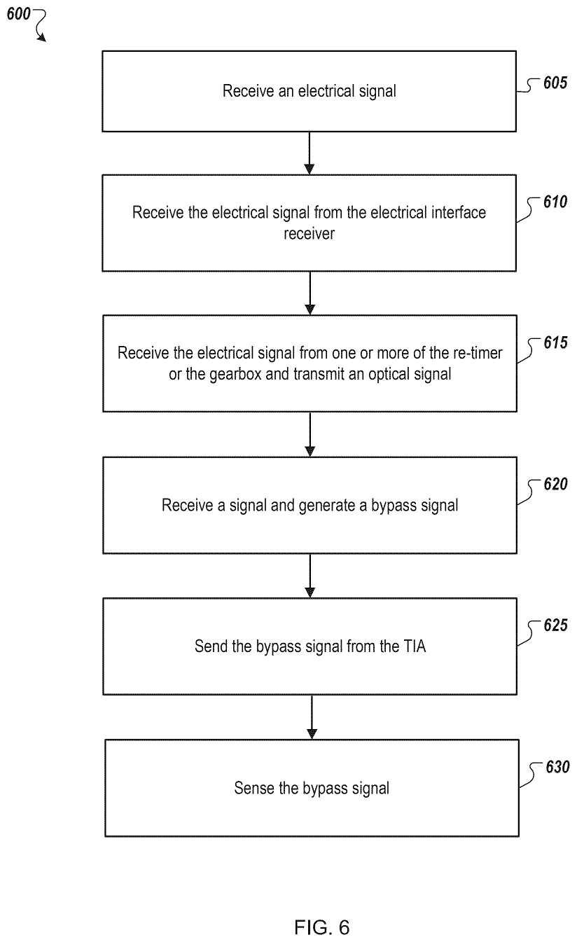

FIG. 6 illustrates a process flow of an example method 600 of sensing trans-impedance amplifier (TIA) output in linear pluggable optics, in accordance with at least one example described in the present disclosure. The method 600 may be arranged in accordance with at least one example described in the present disclosure. The method 600 may be performed by processing logic that may include hardware (circuitry, dedicated logic, etc.), software (such as is run on a computer system or a dedicated machine), or a combination of both, which processing logic may be included in the processor (e.g., the processing device 802 of FIG. 8), the communication system 700 of FIG. 7, or another device, combination of devices, or systems.

The method 600 may begin at block 605 where the processing logic may receive an electrical signal. At block 610, the processing logic may receive the electrical signal from the electrical interface receiver. At block 615, the processing logic may receive the electrical signal from one or more of the re-timer or the gearbox and transmit an optical signal. At block 620, the processing logic may receive a signal and generate a bypass signal. At block 625, the processing logic may send the bypass signal from the TIA. At block 630, the processing logic may sense the bypass signal.

Modifications, additions, or omissions may be made to the method 600 without departing from the scope of the present disclosure. For example, in some examples, the method 600 may include any number of other components that may not be explicitly illustrated or described.

For simplicity of explanation, methods and/or process flows described herein are depicted and described as a series of acts. However, acts in accordance with this disclosure may occur in various orders and/or concurrently, and with other acts not presented and described herein. Further, not all illustrated acts may be used to implement the methods in accordance with the disclosed subject matter. In addition, those skilled in the art will understand and appreciate that the methods may alternatively be represented as a series of interrelated states via a state diagram or events. Additionally, the methods disclosed in this specification are capable of being stored on an article of manufacture, such as a non-transitory computer-readable medium, to facilitate transporting and transferring such methods to computing devices. The term article of manufacture, as used herein, is intended to encompass a computer program accessible from any computer-readable device or storage media. Although illustrated as discrete blocks, various blocks may be divided into additional blocks, combined into fewer blocks, or eliminated, depending on the desired implementation.

FIG. 7 illustrates a block diagram of an example communication system 700 in accordance with at least one example described in the present disclosure. The communication system 700 may include a digital transmitter 702, a radio frequency circuit 704, a device 714, a digital receiver 706, and a processing device 708. The digital receiver 706 and the processing device may be configured to receive a baseband signal via connection 710. A transceiver 716 may comprise the digital transmitter 702 and the radio frequency circuit 704.

In some examples, the communication system 700 may include a system of devices that may be configured to communicate with one another via a wired or wireline connection. For example, a wired connection in the communication system 700 may include one or more Ethernet cables, one or more fiber-optic cables, and/or other similar wired communication mediums. Alternatively, or additionally, the communication system 700 may include a system of devices that may be configured to communicate via one or more wireless connections. For example, the communication system 700 may include one or more devices configured to transmit and/or receive radio waves, microwaves, ultrasonic waves, optical waves, electromagnetic induction, and/or similar wireless communications. Alternatively, or additionally, the communication system 700 may include combinations of wireless and/or wired connections. In these and other examples, the communication system 700 may include one or more devices that may be configured to obtain a baseband signal, perform one or more operations to the baseband signal to generate a modified baseband signal, and transmit the modified baseband signal, such as to one or more loads.

In some examples, the communication system 700 may include one or more communication channels that may communicatively couple systems and/or devices included in the communication system 700. For example, the transceiver 716 may be communicatively coupled to the device 714.

In some examples, the transceiver 716 may be configured to obtain a baseband signal. For example, as described herein, the transceiver 716 may be configured to generate a baseband signal and/or receive a baseband signal from another device. In some examples, the transceiver 716 may be configured to transmit the baseband signal. For example, upon obtaining the baseband signal, the transceiver 716 may be configured to transmit the baseband signal to a separate device, such as the device 714. Alternatively, or additionally, the transceiver 716 may be configured to modify, condition, and/or transform the baseband signal in advance of transmitting the baseband signal. For example, the transceiver 716 may include a quadrature up-converter and/or a digital to analog converter (DAC) that may be configured to modify the baseband signal. Alternatively, or additionally, the transceiver 716 may include a direct radio frequency (RF) sampling converter that may be configured to modify the baseband signal.

In some examples, the digital transmitter 702 may be configured to obtain a baseband signal via connection 710. In some examples, the digital transmitter 702 may be configured to up-convert the baseband signal. For example, the digital transmitter 702 may include a quadrature up-converter to apply to the baseband signal. In some examples, the digital transmitter 702 may include an integrated DAC. The DAC may convert the baseband signal to an analog signal, or a continuous time signal. In some examples, the DAC architecture may include a direct RF sampling DAC. In some examples, the DAC may be a separate element from the digital transmitter 702.

In some examples, the transceiver 716 may include one or more subcomponents that may be used in preparing the baseband signal and/or transmitting the baseband signal. For example, the transceiver 716 may include an RF front end (e.g., in a wireless environment) which may include a power amplifier (PA), a digital transmitter (e.g., 702), a digital front end, an Institute of Electrical and Electronics Engineers (IEEE) 1588v2 device, a Long-Term Evolution (LTE) physical layer (L-PHY), an (S-plane) device, a management plane (M-plane) device, an Ethernet media access control (MAC)/personal communications service (PCS), a resource controller/scheduler, and the like. In some examples, a radio (e.g., a radio frequency circuit 704) of the transceiver 716 may be synchronized with the resource controller via the S-plane device, which may contribute to high-accuracy timing with respect to a reference clock.

In some examples, the transceiver 716 may be configured to obtain the baseband signal for transmission. For example, the transceiver 716 may receive the baseband signal from a separate device, such as a signal generator. For example, the baseband signal may come from a transducer configured to convert a variable into an electrical signal, such as an audio signal output of a microphone picking up a speaker's voice. Alternatively, or additionally, the transceiver 716 may be configured to generate a baseband signal for transmission. In these and other examples, the transceiver 716 may be configured to transmit the baseband signal to another device, such as the device 714.

In some examples, the transceiver 716 may be configured to receive a transmission from the device 714. In some examples, the transceiver 716 may be configured to transmit a baseband signal to the device 714.

In some examples, the radio frequency circuit 704 may be configured to transmit the digital signal received from the digital transmitter 702. In some examples, the radio frequency circuit 704 may be configured to transmit the digital signal to the device 714 and/or the digital receiver 706. In some examples, the digital receiver 718 may be configured to receive a digital signal from the RF circuit and/or send a digital signal to the processing device 708.

In some examples, the processing device 708 may be a standalone device or system, as illustrated. Alternatively, or additionally, the processing device 708 may be a component of another device and/or system. For example, in some examples, the processing device 708 may be included in the transceiver 716. In instances in which the processing device 708 is a standalone device or system, the processing device 708 may be configured to communicate with additional devices and/or systems remote from the processing device 708, such as the transceiver 716 and/or the device 714. For example, the processing device 708 may be configured to send and/or receive transmissions from the transceiver 716 and/or the device 714. In some examples, the processing device 708 may be combined with other elements of the communication system 700.

FIG. 8 illustrates a diagrammatic representation of a machine in the example form of a computing device 800 within which a set of instructions, for causing the machine to perform any one or more of the methods discussed herein, may be executed. The computing device 800 may include a rackmount server, a router computer, a server computer, a mainframe computer, a laptop computer, a tablet computer, a desktop computer, or any computing device with at least one processor, etc., within which a set of instructions, for causing the machine to perform any one or more of the methods discussed herein, may be executed. In alternative examples, the machine may be connected (e.g., networked) to other machines in a local area network (LAN), an intranet, an extranet, or the Internet. The machine may operate in the capacity of a server machine in client-server network environment. Further, while only a single machine is illustrated, the term “machine” may also include any collection of machines that individually or jointly execute a set (or multiple sets) of instructions to perform any one or more of the methods discussed herein.

The example computing device 800 includes a processing device 802, a main memory 804 (e.g., read-only memory (ROM), flash memory, dynamic random access memory (DRAM) such as synchronous DRAM (SDRAM)), a static memory 806 (e.g., flash memory, static random access memory (SRAM)) and a data storage device 816, which communicate with each other via a bus 808.

Processing device 802 represents one or more general-purpose processing devices such as a microprocessor, central processing unit, or the like. More particularly, the processing device 802 may include a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device 802 may also include one or more special-purpose processing devices such as an application specific integrated circuit (ASIC), a field programmable gate array (FPGA), a digital signal processor (DSP), network processor, or the like. The processing device 802 is configured to execute instructions 826 for performing the operations and steps discussed herein.

The computing device 800 may further include a network interface device 822 which may communicate with a network 818. The computing device 800 also may include a display device 810 (e.g., a liquid crystal display (LCD) or a cathode ray tube (CRT)), an alphanumeric input device 812 (e.g., a keyboard), a cursor control device 814 (e.g., a mouse) and a signal generation device 820 (e.g., a speaker). In at least one example, the display device 810, the alphanumeric input device 812, and the cursor control device 814 may be combined into a single component or device (e.g., an LCD touch screen).

The data storage device 816 may include a computer-readable storage medium 824 on which is stored one or more sets of instructions 826 embodying any one or more of the methods or functions described herein. The instructions 826 may also reside, completely or at least partially, within the main memory 804 and/or within the processing device 802 during execution thereof by the computing device 800, the main memory 804 and the processing device 802 also constituting computer-readable media. The instructions may further be transmitted or received over a network 818 via the network interface device 822.

While the computer-readable storage medium 824 is shown in an example to be a single medium, the term “computer-readable storage medium” may include a single medium or multiple media (e.g., a centralized or distributed database and/or associated caches and servers) that store the one or more sets of instructions. The term “computer-readable storage medium” may also include any medium that is capable of storing, encoding or carrying a set of instructions for execution by the machine and that cause the machine to perform any one or more of the methods of the present disclosure. The term “computer-readable storage medium” may accordingly be taken to include, but not be limited to, solid-state memories, optical media and magnetic media.

In some examples, the different components, modules, engines, and services described herein may be implemented as objects or processes that execute on a computing system (e.g., as separate threads). While some of the systems and methods described herein are generally described as being implemented in software (stored on and/or executed by hardware), specific hardware implementations or a combination of software and specific hardware implementations are also possible and contemplated.

Terms used herein and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, it is understood that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc. For example, the use of the term “and/or” is intended to be construed in this manner.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additionally, the use of the terms “first,” “second,” “third,” etc., are not necessarily used herein to connote a specific order or number of elements. Generally, the terms “first,” “second,” “third,” etc., are used to distinguish between different elements as generic identifiers. Absence a showing that the terms “first,” “second,” “third,” etc., connote a specific order, these terms should not be understood to connote a specific order. Furthermore, absence a showing that the terms first,” “second,” “third,” etc., connote a specific number of elements, these terms should not be understood to connote a specific number of elements. For example, a first widget may be described as having a first side and a second widget may be described as having a second side. The use of the term “second side” with respect to the second widget may be to distinguish such side of the second widget from the “first side” of the first widget and not to connote that the second widget has two sides.

All examples and conditional language recited herein are intended for pedagogical objects to aid the reader in understanding the invention and the concepts contributed by the inventor to furthering the art, and are to be construed as being without limitation to such specifically recited examples and conditions. Although examples of the present disclosure have been described in detail, it should be understood that the various changes, substitutions, and alterations could be made hereto without departing from the spirit and scope of the present disclosure.

What is claimed is:

1. A device comprising:
a transmit path comprising an electrical-optical interface operable to receive an electrical signal and send an optical signal;
a receive path comprising a trans-impedance amplifier (TIA) operable to send a bypass signal; and
an optical interface receiver coupled to the receive path, wherein the optical interface receiver is operable to sense the bypass signal.

2. The device of claim 1, wherein the optical interface receiver is operable to send a sensed bypass signal to a module interface.

3. The device of claim 1, wherein the optical interface receiver is operable to:
monitor forward error-correction (FEC) statistics of the receive path;
collect FEC statistics of the receive path; and
report the FEC statistics to a module interface.

4. The device of claim 1, wherein the optical interface receiver is operable to send feedback to the TIA using the bypass signal.

5. The device of claim 4, wherein the optical interface receiver is operable to send feedback to the TIA using one or more signal conditions of the bypass signal.

6. The device of claim 5, wherein the one or more signal conditions comprise a voltage swing or a channel roll-off.

7. The device of claim 4, wherein the feedback is used to adjust one or more of an internal gain of the TIA or an equalization of the TIA.

8. The device of claim 1, wherein the receive path is operable to use a duty cycle to reduce power consumption.

9. A method comprising:
receiving, on a receive path, a bypass signal from a trans-impedance amplifier (TIA); and
sensing, on the receive path, the bypass signal using an optical interface receiver coupled to the receive path.

10. The method of claim 9, further comprising sending, using the optical interface receiver, a sensed bypass signal to a module interface.

11. The method of claim 9, further comprising sending, using the optical interface receiver, feedback to the TIA from a sensed bypass signal.

12. The method of claim 11, further comprising sending, using the optical interface receiver, the feedback to the TIA using one or more signal conditions of the sensed bypass signal.

13. The method of claim 11, further comprising adjusting one or more of an internal gain of the TIA using the feedback or an equalization of the TIA using the feedback.

14. The method of claim 9, further comprising:
monitoring forward error-correction (FEC) statistics of the receive path;
collecting the FEC statistics of the receive path; and
reporting the FEC statistics to a module interface.

15. A device comprising:
a transmit path comprising:
an electrical interface receiver operable to receive an electrical signal;
one or more of a re-timer or a gearbox operable to receive the electrical signal from the electrical interface receiver; and
an optical interface transmitter operable to receive the electrical signal from one or more of the re-timer or the gearbox and transmit an optical signal; and
a receive path comprising:
a trans-impedance amplifier (TIA) operable to receive a signal and generate a bypass signal;
a bypass path operable to send the bypass signal from the TIA; and
an optical interface receiver operable to sense the bypass signal.

16. The device of claim 15, wherein the optical interface receiver is operable to send the bypass signal to a module interface.

17. The device of claim 15, wherein the optical interface receiver is operable to send feedback to the TIA using the bypass signal.

18. The device of claim 17, wherein the optical interface receiver is operable to send feedback to the TIA using one or more signal conditions of the sensed bypass signal.

19. The device of claim 17, wherein the feedback is used to adjust one or more of an internal gain of the TIA or an equalization of the TIA.

20. The device of claim 15, wherein the optical interface receiver is operable to:
monitor forward error correction (FEC) statistics;
collect the FEC statistics; and
report the FEC statistics to a module interface.
